(19) United States
(12) Patent Application Publication
(10) Pub. No.: US 2014/0233197 A1
(43) Pub. Date: Aug. 21, 2014

(54) COVER ELEMENT AND HOUSING DEVICE FOR USE OF THE COVER ELEMENT

(71) Applicant: HKR Seuffer Automotive GmbH & Co. KG, Kupferzell (DE)

(72) Inventors: Oliver Schwab, Weinsberg (DE); Franz Herdtweck, Cripsenhofen (DE); Wolfgang Bass, Bretzfeld-Adolzfurt (DE)

(73) Assignee: HKR Seuffer Automotive GmbH & Co. KG, Kupferzell (DE)

(21) Appl. No.: 14/171,944

(22) Filed: Feb. 4, 2014

(30) Foreign Application Priority Data
Feb. 15, 2013 (DE) 10 2013 002 629.6

(51) Int. Cl. H05K 5/03; H05K 5/06

(52) U.S. Cl. CPC H05K 5/03; H05K 5/062
USPC 361/757; 361/752; 220/315

(57) ABSTRACT

The invention concerns a cover element (2) connectable to a housing lower portion (3) for covering same to form a housing device (1), wherein the cover element is formed in one piece as a shaped portion, the lower surface (16) of the cover element, that faces in the direction of the lower portion, is so designed that it follows the contour of the inside surface of the lower portion, and projections and recesses in the lower surface of the cover element are of such a configuration that recesses in the inside surface of the lower portion are at least partially filled and projections on the inside surface of the lower portion are at least partially surrounded in positively locking relationship.

### CROSS REFERENCE TO RELATED APPLICATION

This application claims priority under 35 USC §119 to German Patent Application No. 10 2013 002 629.6 filed on Feb. 15, 2013, which application is hereby incorporated by reference in its entirety.

### TECHNICAL FIELD

The present invention concerns a cover element and in particular a cover element in the form of a shaped portion for covering a housing lower portion, as well as a housing device for use of the cover element.

### BACKGROUND OF THE INVENTION

DE 197 28 992 A1 discloses a housing for a semiconductor body (semiconductor chip), wherein the semiconductor body is fitted into and fixed in a lower part of a housing. The remaining space within the housing is filled by casting so that the housing is closed off and an individual component is provided in conjunction with the semiconductor body.

U.S. Pat. No. 7,462,919 B2 discloses a pressure-sensitive component, by means of which switching functions can be triggered. A pressure-sensitive semiconductor chip is embedded in plastic layers and enclosed thereby. A pressure for triggering a switching process can be applied from above. The arrangement can also have a plastic sheathing produced by a casting process.

DE 102 25 993 A1 discloses an arrangement in which an electronic component which in operation gives off heat is held fast by means of a spring element and pressed against a main body. In that case the main body can also serve as a cooling body. The spring element is fixed to the main body by means of a mechanical device and exerts the required pressure on the electronic component.

In the above-indicated known arrangements a respective housing or corresponding housing portions are of a multi-part configuration and are produced by different casting procedures (generally by means of a plastic injection molding process). In every case an expensive and laborious assembly procedure is required. Different materials are also required to produce housing portions or spring elements, and those materials respectively require separate manufacturing and assembly processes. It is further generally difficult for a plurality of and in part different components or semiconductor chips to be arranged in one housing.

### SUMMARY OF THE INVENTION

Therefore the object of the present invention is to design a cover element of the kind set forth in the opening part of this specification in such a way that at least one housing lower portion is effectively, permanently and securely closed by means of the cover element to form a housing device and the cover element can be produced in a simple and inexpensive fashion.

According to the invention that object is attained by means of a cover element and by means of a housing device using the cover element, having the features of the accompanying claims.

The present invention therefore concerns a cover element connectable to a housing lower portion for covering same, wherein the cover element is formed in one piece as a shaped portion, the lower surface of the cover element, that faces in the direction of the lower portion, is so designed that it follows the contour of the inside surface of the lower portion, and projections and recesses in the lower surface of the cover element are of such a configuration that recesses in the inside surface of the lower portion are at least partially filled and projections on the inside surface of the lower portion are at least partially surrounded in positively locking relationship.

The arrangement of the cover element according to the invention permits total closure of the housing lower portion on to which the cover element is fitted, wherein the space formed in the interior of the housing lower portion and the cover element is completely sealed off to prevent the ingress of dirt and moisture. The cover element can be connected to the housing lower portion so as to ensure a secure connection between those two components. The cover element is formed in one piece as a shaped portion. In that case the inside surface (inwardly disposed surface) of the cover element is of such a configuration that it at least partially follows the contour of the inside surface of the housing lower portion. Projections and recesses in the inside surface of the cover element are so provided that respective recesses in the inside surface of the housing lower portion are at least partially filled up and projections or protruding parts of the inside surface of the housing lower portion are at least partially surrounded in positively locking relationship.

In that way component parts of differing sizes, that are arranged within the housing lower portion, can be partially enclosed so that those components can be held fast in position. In the event of vibrations corresponding vibrations can be damped as the material of the cover element at least partially encloses the components and parts protruding at the inside surface of the housing lower portion so that a damping action is achieved in the case of vibrations. In addition a device on which the parts or components are disposed like for example a printed circuit board can be held fast and fixed in one position by the cover element by means of the protruding parts and components being surrounded in positively locking relationship.

The cover element according to the invention thus affords a plurality of functions, while complete sealing integrity of the housing lower portion after fitment of the cover element is guaranteed. Mechanical oscillation or vibration damping is effected insofar as individual parts of the inside surface of the housing lower portion are at least partially enclosed by the material of the cover element. That securely and permanently provides a large-area holding function substantially adapted to the contours of the inside surface of the housing lower portion. There is no need for an expensive and laborious process for completely or partially filling by casting the space above the inside surface of the cover lower portion. Rather the configuration of the cover element according to the invention ensures simple manufacture and simple assembly so that after insertion of components and other parts in the housing lower portion and a cover element adapted to those contours the required assembly procedure is concluded after the cover element has been fitted in place. Inexpensive manufacture of the entire housing including the housing lower portion and the cover element according to the invention is thus guaranteed.

Further configurations of the present invention are recited in the appendant claims.

In the case of the cover element the inside surface of the lower portion is formed by a printed circuit board on which electric and electronic components are arranged and the cover element is adapted to follow the individual contour of the printed circuit board including the components. Predetermined components disposed on the printed circuit board can be at least partially surrounded by the cover element in positively locking relationship.

At its lower surface the cover element can have a contact surface which after connection of the cover element to the lower portion rests on an oppositely disposed contact surface of the lower portion in areal and sealing relationship.

The first contact surface of the cover element can project into the lower portion when the cover element is fitted on to the lower portion.

The first contact surface of the cover element can rest partially on the printed circuit board and the printed circuit board can be fixed in the lower portion.

Projecting contact pressure regions can be provided at the lower surface of the cover element in the region of components arranged on the printed circuit board, which projecting contact pressure regions rest elastically on the respective components at predetermined locations thereon.

The cover element can have an annular contact surface at its lower surface and provided in the region of said contact surface can be a contact pressure region which rests sealingly on the second contact surface of the lower portion and extends over the entire configuration of the annular contact surface of the cover element.

The cover element can be formed from a foam material with a component or with a plurality of components or from an elastic multi-component material on a silicone base or TPE.

The present invention also concerns a housing device comprising a housing lower portion into which a printed circuit board equipped with electric and electronic components can be fitted and the above-described cover element for covering the housing lower portion. With insertion of the cover element into the housing lower portion it is possible to form a housing device which is completely closed and wherein the space formed in the interior of the housing lower portion and the cover element is totally sealed off to prevent ingress of dirt and moisture.

### BRIEF DESCRIPTION OF THE DRAWINGS

The present invention is described in greater detail hereinafter by means of embodiments by way of example with reference to the drawing in which:

FIG. 1 shows a sectional view of a housing device including the cover element according to a first embodiment of the present invention,

FIG. 2 shows a sectional view of a housing device with the cover element according to a second embodiment of the present invention,

FIG. 3 shows a sectional view of parts of the views in FIGS. 1 and 2 with details regarding the arrangement of semiconductor components, and

FIG. 4 shows a sectional view of the arrangement of FIG. 2 of the second embodiment, with a sealing element additionally being provided.

### DETAILED DESCRIPTION

### First Embodiment

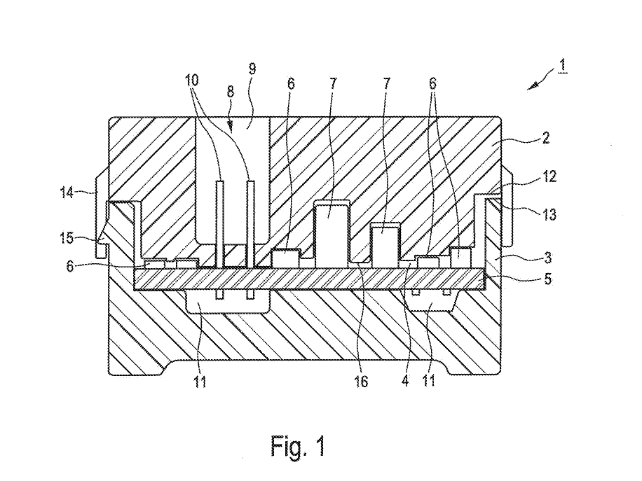

Referring to FIG. 1 a first embodiment of the present invention is described hereinafter.

FIG. 1 shows a housing device 1 in which a cover element 2 according to the invention is used. Besides the cover element 2, the housing device 1 includes a housing lower portion 3 which is so designed that the cover element 2 and the housing lower portion 3 can be connected together to form the housing device 1. The housing lower portion 3 is referred to hereinafter for simplicity as the lower portion 3.

Formed in the housing device 1 between the cover element 2 and the lower portion 3 is an internal space 4 in which parts to be disposed and protected by means of the housing device 1, like for example a printed circuit board 5 having a plurality of electric and electronic components and mechanical elements, are disposed. The present invention in connection with the cover element 2 is not limited to the arrangement of the printed circuit board 5 with further components. For the sake of simplicity of the drawing however the present invention is described here using the example of the arrangement of the printed circuit board 5 with components and further parts within the housing device 1.

In the view in FIG. 1 the printed circuit board 5 is fitted into the internal space 4 and specifically into the lower portion 3 of the housing device 1. The lower portion 3 is of such a configuration that it can receive the printed circuit board 5 in the form of a flat unit. Provided on the printed circuit board 5 are the electric and electronic components, for example in the form of small components 6 which are of a predominantly flat form, and larger components 7 which are of a greater height in comparison with their base surface with which they are fixed on the printed circuit board 5 and which therefore project from the printed circuit board 5. The smaller components 6 are smaller or lower than a predetermined mean height of components or constituent parts and the larger components 7 are higher than the one predetermined mean height of components or constituent parts (measured from the upper surface of the printed circuit board 5 to the upper edge of the respective components 6 or 7). The smaller components or constituent parts also include components which are arranged flat on the printed circuit board (for example certain configurations of transistors).

In FIG. 1 for example there are two such larger components 7 in respect of which the height in a direction perpendicular to the surface of the printed circuit board 5 is greater than at least one of the edge lengths of the contact surface on the printed circuit board 5. In comparison the smaller components 6 are substantially flatter and lie with a small height flat on the printed circuit board 5. The smaller and larger components 6 and 7 can be electrically contacted and mechanically fixed on the printed circuit board 5 by means of connecting legs. In addition they can be in the form of surface-mount device components (SMD components). The components 6 and 7 on the printed circuit board are part of a circuit arrangement on the printed circuit board.

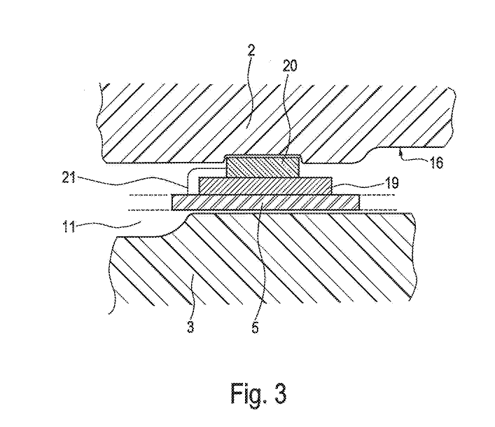

The form of the smaller and larger components 6 and 7 is dependent on their respective function, in which respect integrated circuits (ICs) are of a rather flat form while capacitors (in particular electrolytic capacitors) and coils are of a greater height and are thus to be considered among the larger components 7 as they project to a greater extent above the printed circuit board 5 and are generally higher than the predetermined mean height. Individual electronic components like for example power semiconductors like field effect transistors can be arranged in conjunction with a suitable cooling body on the printed circuit board 5. Such an arrangement is further described hereinafter with reference to FIG. 3. The components or constituent parts on the printed circuit board 5 represent projections of differing height on the printed circuit board 5.

Looking at the view in FIG. 1 there is also at least one plug region 8, wherein provided in the cover element 2 is an opening region 9 in which there project contact pins 10 of the plug region 8, that are fixed on the printed circuit board 5. Electrical contact can be made with the electric and electronic components 6 and 7 on the printed circuit board 5 when a corresponding plug is inserted, by means of the contact pins 10 which are provided in a predetermined number depending on the need involved.

If it is required for components or parts thereof to be arranged on the underside of the printed circuit board 5, shown in FIG. 1, then suitable recesses 11 are provided in the lower portion 3. In other respects the printed circuit board preferably lies in contact over a large area on the upper surface of the lower portion 3.

The cover element 2 connectable to the lower portion 3 is preferably formed in one piece. The cover element 2 comprises an elastic material like for example a plastic material and can preferably be produced by means of injection molding.

The external form of the cover element 2 and in particular in regard to the external dimensions is adapted to the respective external dimensions of the lower portion 3 for forming the housing device 1. After the cover element 2 and the lower portion 3 are assembled to form the housing device 1 an edge region 12 (first edge region) of the cover element 2 lies on an edge region 13 (second edge region) of the lower portion 3 so that in conjunction with the elastic material at least of the cover element 2, secure contact which is in sealing relationship over the respective entire edge regions 12 and 13 is achieved. The cover element 2 can also project into the lower portion 3 of the housing device 1 in positively locking relationship.

In addition there are fixing elements 14 (on the cover element 2) and 15 (on the lower portion 3) so that a fixed connection can be formed between the cover element 2 and the lower portion 3, preferably in the form of a latching connection. Such an arrangement is indicated in FIG. 1 on the left-hand side of the housing device 1. To provide a secure connection a plurality of those fixing elements 14 and 15 are arranged distributed over the entire periphery of the edge regions 12 and 13, in dependence on the requirement involved and on the geometrical dimensions of the housing device 1.

In the diagrammatic view in FIG. 1, a predetermined contour is formed within the internal space 4 by the arrangement of the electric and electronic components 6 and 7 of differing sizes and structural heights, and a lower surface 16 of the cover element 2 is designed in such a way that it follows substantially and thus partially the contour of the printed circuit board 5 including the smaller and larger components 6 and 7 as well as the plug regions 8. The contour of the printed circuit board 5 including the smaller and larger components 6 and 7 and the plug regions 8 forms an inside surface of the lower portion 3.

In that respect the lower surface 16 of the cover element 2 is of such a configuration that the lower surface 16 is in contact from above with individual components 6 and 7 arranged on the printed circuit board 5 as shown in FIG. 1 and partially fills up intermediate spaces between the respective components 6 and 7. In this respect especially the larger components 7 of a height projecting considerably above the printed circuit board 5 are at least partially surrounded by the material of the cover element 2. As shown in FIG. 1 therefore the larger components 7 of a sufficient height are partially enclosed by the cover element 2 and are thus surrounded over at least half of their extent perpendicularly to the printed circuit board 5 by the material of the cover element 2. The larger components 7 which represent projections which are marked relative to the surface of the printed circuit board 5 are thus partially enclosed by the cover element 2, wherein the material of the cover element 2 is in contact with the larger component 7 at least in the upper region, remote from the printed circuit board 5, of the respective larger component 7.

Therefore after being connected to the lower portion 3, the cover element 2 of the housing device 1 can be in contact with parts of its lower surface 16 with individual ones of the components 6 and 7, entirely or in part. The components 6 and 7 on the printed circuit board as well as the plug regions form projections and therebetween recesses, the cover element 2 having corresponding recesses and projections.

In connection with the elastic material of the cover element 2, contact pressure forces can be exerted in the direction of the printed circuit board 5 on the components 6 and 7 irrespective of their height as a projection on the inside surface of the lower portion 3 relative to the printed circuit board 5 and their respective mechanical configuration and external form. Thus preferably the larger components 7 and also in dependence on the need involved the smaller components 6 are at least partially embedded in positively locking relationship in corresponding recesses in the lower surface 16 of the cover element 2, irrespective of the fact that in the diagrammatic and simplified view in the Figures small spacings can occur between the components 6 and 7 and the lower surface 16 of the cover element 2 and further surfaces which are actually bearing against each other.

With the possibility that forces can be exerted on the respective components 6 and 7 in the direction of the printed circuit board 5 after the cover element 2 has been fitted on to the lower portion 3, the printed circuit board 5 can be pressed in its position against the lower portion 3 and securely fixed. Displacement of the printed circuit board 5 relative to both the cover element 2 and also the lower portion 3 is not possible by means of that arrangement in the housing device 1.

The one-piece arrangement of the cover element 2 in conjunction with an elastic material leads to the following advantages in regard to the manufacture of the cover element 2 and in regard to use in the above-described housing device 1.

The cover element 2 is produced in one piece, preferably from an elastic material, so that a multi-part structure and a plurality of materials are not required. With its secure and elastic fit in conjunction with the edge regions 12 and 13 the cover element 2 provides for complete sealing integrity to prevent contamination and the ingress of moisture so that the parts arranged in the internal space like the printed circuit board 5 and the components 6 and 7 thereon are effectively and permanently protected from an effect of contamination or the ingress of moisture.

In addition, the printed circuit board 5 is securely fixed in its position in the lower portion 3 by the application of a force on at least a part of the components 6 and 7 (from above in FIG. 1) in the direction of the printed circuit board 5. With the larger components 7 and also the smaller components 6 being at least partially enclosed (in positively locking relationship) they can be effectively held relative to the printed circuit board 5. In the event of vibrations, for example upon use in an industrial machine or in a motor vehicle, the arrangement effectively prevents individual components, at least the larger components 7, being able to come loose on the printed circuit board 5. Detachment of the components 6 or 7 from the printed circuit board 5, for example by fracture of connecting devices or solder joins, is effectively prevented. With the cover element 2 being made from an elastic material, for example a non-conducting material, it is also possible to achieve reliable electrical insulation between the components, for example to prevent electric flash-over.

The cover element 2 in the configuration according to the invention thus affords a large number of functions at the same time and in a very simple manner and in conjunction with inexpensive manufacture. Besides the function as a cover element, it also provides for reliable sealing of the housing device 1, vibration damping is effected under unfavorable conditions of use, and the fact that larger components 7 on the printed circuit board 5 are enclosed at least partially in positively locking relationship provides that the components 6 and 7 are securely held in position even in the event of severe vibration or other forces acting from the exterior. In addition, thermal insulation is afforded in relation to considerable temperature fluctuations from the exterior as well as electrical insulation on the printed circuit board 5.

Exerting forces by means of the elastic properties of the cover element 2 on a plurality of components 6 and 7 in the direction of the printed circuit board 5 provides on the one hand for fixing of the printed circuit board 5 in the lower portion 3 and also holding fast at least the larger components 7 and pressing a plurality of the components 6 and 7 against the printed circuit board 5, while at the same time vibration damping and electrical insulation are implemented. There is no need for completely casting material in the interior of the lower portion 3 and around the printed circuit board 5 and the components 6 and 7 disposed thereon. The above-specified advantages can be achieved with the formation of the cover element 2 preferably in one piece in the form of a shaped portion made from an elastic material.

The lower surface 16 of the cover element 2 is thus dependent on the configuration of the printed circuit board 5 and the number, configuration and positioning of the respective components 6 and 7 and also corresponding plug regions 8 on the printed circuit board 5. The cover element 2 is thus adapted in manufacture to the respective configuration of a given printed circuit board 5 and thus a given contour thereof. For each printed circuit board 5 including the respective components and components 6, 7 and 8 by which the inside surface of the lower portion 3 is formed, a specific cover element 2 has to be formed, which partially follows the contour involved in the specific configuration of the printed circuit board 2. The mechanical configuration of the equipped printed circuit board 5 is thus dependent on the circuit arrangement implemented as well as the choice (that is to say the type) of the components 6 and 7 used as well as further components and their positioning on the printed circuit board 5.

With a change in components (kind and position thereof) on the printed circuit board 5, a cover element 2 of a different configuration is generally required. Each configuration of the inside surface of the lower portion 3 (and thus the printed circuit board 5 in conjunction with the components 6, 7 and 8) requires an individual configuration for the cover element 2. In detail in producing the cover element 2 from an elastic material, the contour of the surface (inside surface), that results from the respective circuit arrangement to be disposed on the printed circuit board 5, with the respective components 6, 7 and 8, is determined and the cover element 2 is formed as an approximate negative shape of the contour of that surface of the lower portion 3. Accordingly the lower surface 16 of the cover element 2 at least partially follows the contour of the inside surface of the lower portion 3. In detail in that respect projections and recesses in the lower surface 16 of the cover element 2 are of such a configuration that recesses in the inside surface of the lower portion 3 are at least partially filled up and projections on the inside surface of the lower portion 3 are at least partially surrounded in positively locking relationship.

### Second Embodiment

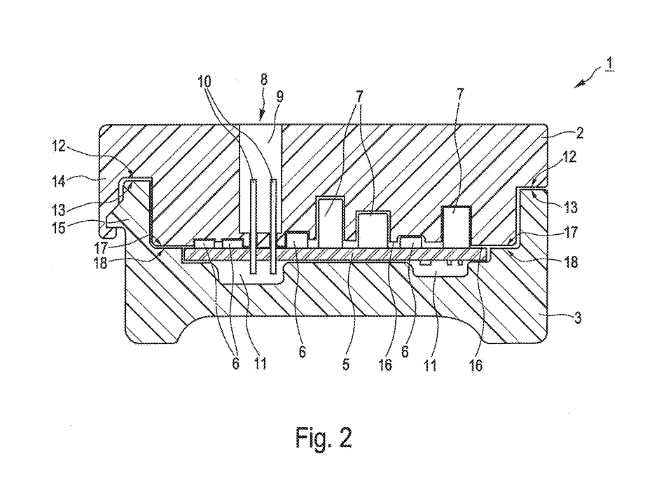

With reference to FIG. 2 a second embodiment of the present invention is described hereinafter. Similar or identical components or constituent parts are identified in the description of the second embodiment by the same references as in the first embodiment.

FIG. 2 shows a similar arrangement of the cover element 2 as shown in FIG. 1, the housing device 1 comprising the lower portion 3 and the cover element 2. The cover element 2 and the lower portion 3 can be connected together. For that purpose there can be fixing elements 14 and 15 and a latching connection can be made.

In the same manner as in the first embodiment, the second embodiment provides that the contour of the lower surface 16 of the cover element 2 approximately follows the contour of the inside surface of the printed circuit board 5 in conjunction with components 6 and 7 of differing size, shape and arrangement on the printed circuit board 5. Likewise there can be at least one plug region 8 with an opening region 9 and contact pins 10. A plug can be fitted into the opening region 9 to make an electrical contact for operation of the circuit arrangement which is implemented in conjunction with the components 6 and 7 on the printed circuit board 5.

In the second embodiment also a force directed in the direction of the printed circuit board 5 can be exerted in respect of the cover element 2 on the individual components 6 and 7, in which case the higher components 7 which project considerably above the surface of the printed circuit board 5 are at least partially surrounded by the material of the cover element 2.

Unlike the first embodiment in the second embodiment a contact surface is provided at the lower surface 16 of the cover element 2, which contact surface represents a first contact surface 17. The printed circuit board 5 is arranged in the lower portion 2 in such a way that a contact surface 18 (second contact surface) is also defined at the outer edge of the printed circuit board 5 in the lower portion 3, the second contact surface 18 surrounding a recess in the lower portion 3, into which the printed circuit board 5 is at least partially fitted in positively locking relationship in the lower portion 3. The first contact surface 16 of the cover element 2 bears partially against the second contact surface 18 of the lower portion 3. Both contact surfaces 17 and 18 can be flat horizontal or also inclined annular surfaces around the printed circuit board 5, wherein the respective inclination is identical so as to ensure sealing contact between the two contact surfaces 17 and 18. Thus, besides the sealing integrity in respect of the housing device 1 by way of the first and second edge regions 12 and 13, described hereinbefore in connection with the first embodiment, the second embodiment provides for a further sealing action by way of the first and second contact surfaces 17 and 18 between the cover element 2 and the housing lower portion 3 for forming the housing device 1. A complete sealing integrity can be achieved in that way, even if the housing device 1 is exposed to a strong flow of air or spray water to an increased extent or over a prolonged period of time, as is possible for example in a situation involving use in an industrial machine or a motor vehicle.

In addition the width of the first contact surface 17 of the cover element 2 is greater than the width of the second contact surface 18 of the lower portion 3 so that the first contact surface 17 extends further into the interior of the housing device 1 and also rests on an edge region of the printed circuit board 5. Thus, besides the improved sealing integrity, further fixing of the printed circuit board 5 in the lower portion 3 is also achieved over at least a part of the periphery of the printed circuit board 5, in addition to the printed circuit board 5 being pressed into contact in the lower portion 3 as a consequence of forces being applied to the various components 6 and 7 by the elastic material of the cover element 2 when fitted on. Even in the event of severe vibration or high external forces this means that displacement of the printed circuit board 5 or vibration thereof is no longer possible. The vibration-damping effect by the elastic material of the cover element 2 ensures that the printed circuit board 5 is fixed securely and in almost vibration-free fashion in the lower portion 3, including the components 6 and 7 arranged on the printed circuit board 5. The further advantages which are achieved with the configuration of the cover element 2 according to the first embodiment are also achieved with the cover element 2 of the second embodiment. Accordingly the multiple functions which exist at the same time and which are described in connection with the first embodiment also apply to the cover element 2 of the second embodiment.

FIG. 3 shows a supplement to the arrangement of FIGS. 1 and 2 of the first and second embodiments.

Various different components which are arranged in the form of smaller or larger components 6 and 7 on the printed circuit board 5 were described in connection with the first and second embodiments. Those components 6 and 7 are urged elastically in the direction of the printed circuit board 5 with a corresponding predetermined force after insertion of the cover element 2 into the lower portion 3, on the one hand, while on the other hand, in particular the larger components 7 are surrounded at least partially in positively locking relationship by the material of the second cover element. This therefore ensures a secure fixed hold (fixing) and damping of vibrations or oscillations.

FIG. 3 shows the arrangement of a semiconductor component like for example a power semiconductor (for example a field effect transistor or the like) which in operation and especially in relation to a large number of switching operations for the provision of clock-controlled signals gives off waste heat. For that purpose such semiconductor components are arranged in conjunction with a cooling body.

FIG. 3 shows in the lower region in a sectional view showing part of the arrangement, a part of the lower portion 3 with the printed circuit board 5 disposed thereon. Arranged on the printed circuit board 5 is a cooling body 19 comprising a heat-conducting material, preferably a metal (for example copper, aluminum). The cooling body 19 is of mechanical dimensions (width, height and depth) which depend on the mechanical dimensions and the size and conversion of the waste heat of a semiconductor component 20 to be cooled. Preferably the cooling body 19 is arranged directly on the printed circuit board 5 while the housing of the semiconductor component 20 is disposed on the cooling body 19. A part of the cover element 2 is shown above the semiconductor component 20 in FIG. 3, wherein the lower surface 16 of the cover element 2 partially follows the contour of the inside surface of the lower portion 3 and thus the printed circuit board 5 including components (6, 7, 20) and constituent parts arranged thereon.

The elastic material of the cover element 2 rests on the semiconductor component 20 and is pressed with a downwardly directed force on to the cooling body 19 which lies on the printed circuit board 5. In that way on the one hand the semiconductor component 20 is secured to prevent displacement thereof as it preferably lies in an at least small recess in the lower surface 16 of the cover element 2, while on the other hand it is capable of giving off waste heat that is produced to the cooling body 19 as the semiconductor component 20 rests with good thermal contact on the cooling body 19 by virtue of a corresponding pressure. In addition the lower surface 16 of the cover element 2 can be of such a configuration that connecting lines 21 of the semiconductor component 20 are also fixed by the elastic material of the cover element 2.

In that way it is possible on the one hand to prevent a further feed of heat to the semiconductor component 20 from the exterior by means of the elastic material of the cover element, while on the other hand it is possible to ensure an adequate dissipation of heat from the semiconductor component 20 to the cooling body 19.

In a modification in that respect it is possible for both the semiconductor component 20 and also the cooling body 19 to be arranged together at an angle, preferably a right angle, to the printed circuit board 5, in which case the two parts 20 and 21 then project into a corresponding recess in the cover element 2 and in that way are mechanically supported on the one hand while on the other hand they are brought into close contact with each other. This modification achieves the same advantages.

### Modifications

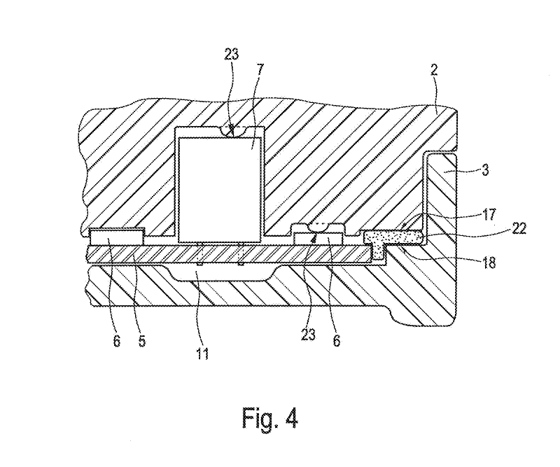

FIG. 4 shows a sectional view of the arrangement of FIG. 2 of the second embodiment, with a sealing element 22 additionally being provided.

The cover element 2 and the lower portion 3 respectively have the first and second contact surfaces 17 and 18 shown in connection with the second embodiment. While in the second embodiment the two contact surfaces 17 and 18 touch each other in flush relationship over a large area and thus afford an additional sealing action, the sealing element 22 is provided in the modification shown in FIG. 4. The sealing element 22 comprises an elastic material and preferably a plastic material, the sealing element 22 being arranged both between the outer edge of the printed circuit board 5 and the lower portion 3 and also between the two contact surfaces 17 and 18. The sealing element 22 is enclosed between the contact surfaces 17 and 18 so that a further improved sealing action is achieved. At the same time the printed circuit board 5 is fixed elastically and securely in the lower portion 3.

FIG. 4 further shows, over a part of the components 6 and 7 and thus at the lower surface 16 of the cover element 2, contact pressure regions 23 which are provided in relation to at least a part of the components 6 and 7 and in relation to which the lower surface 16 of the cover element 2 is of such a configuration that the contact pressure region 23 comprises a projection smaller than the upper surface of the respective component 6 or 7 disposed therebeneath, while the pressure exerted on the respective component 6 or 7 is elastically exerted only by way of the contact pressure region 23.

It is possible in that way, in targeted fashion in dependence on the nature of the components 6 and 7 and the respective mechanical dimensions and the arrangement of the component 6 and 7 on the printed circuit board 5, to exert the pressure in the center of or on a preferred side of the component 6 and 7. Thus, utilising a given configuration for the surface of the respective component 6 or 7, it is possible specifically to exert the pressure applied from above in the Figures in the direction of the printed circuit board 5 for optimum fixing both of the printed circuit board 5 and also the respective components 6 and 7. Damping of possible oscillations and micromovements of the printed circuit board 5 and/or the respective components 6 and 7, that is further wanted, is ensured in the same fashion as in the first and second embodiments.

If the contact pressure region 23 bears against the respective components 6 and 7 at predetermined locations differing forces can be exerted in the sense of the direction of the force and a magnitude in respect of the force on the components 6 and 7, in dependence on the size and configuration of the contact pressure region 23. Corresponding to an arrangement of the contact pressure region 23 at the lower surface 16 of the cover element 2 in such a way that the contact pressure region 23 is in contact only with given locations of a respective component 6 and 7, it is possible in dependence on the type of the component, its position on the printed circuit board 5 and its mechanical dimensions, to exert a greater or smaller force in connection with a predetermined direction, in specifically targeted fashion. Provided at the lower surface 16 of the cover element 2 in the region of a respective predetermined component 6 or 7 there is at least one contact pressure region 23, in which respect it is also possible to provide a plurality of contact pressure regions which are in contact with the respective predetermined component 6 or 7 at different locations and which thus exert forces in predetermined directions in specifically targeted fashion.

In addition the cover element 2 can also have a contact pressure region 23 at its lower surface 16 and the annular contact surface 17 in the region of that contact surface, which contact pressure region bears sealingly against the second contact surface 18 of the lower portion 3 and extends over the entire extent of the annular contact surface 17 of the cover element 2.

The advantages described hereinbefore in relation to the first and second embodiments can also be achieved with this arrangement in accordance with the modification shown in FIG. 4.

Besides the above-described multiple functions of the cover element 2 in the configuration according to the invention, the elastic material of the cover element 2 can provide that tolerances in the mechanical dimensions of the components and as a result of fitment of the respective components 6 and 7 on the printed circuit board 5 as well as assembly of the printed circuit board 5 including the components 6 and 7 in the lower portion 3 can be compensated so that irrespective of such tolerances the holding action in relation to the components 6 and 7 as well as the printed circuit board 5 and the damping action in relation to vibrations is guaranteed. The stated advantages are also guaranteed in the event of inevitable thermal expansion and contraction of the printed circuit board 5, the respective components 6 and 7 and the entire housing device 1, for example upon use in a motor vehicle involving different ambient and operating temperatures.

In regard to the configuration of the first and second edge regions 12 and 13 and the two contact surfaces 17 and 18 it is also possible to provide a rabbet configuration in the sense of a peripherally extending stepped arrangement of the respective mutually contacting surfaces so that it is possible at the same time to achieve a high degree of sealing integrity and mechanical stability.

The cover element 2 and the lower portion 3 of the housing device 1 can be made from the same material or from different materials. Preferably the cover element 2 is made in one piece from an elastic material and preferably the lower portion 3 is formed from a material of higher strength. In that case stability of the overall housing device 1 can be improved.

In regard to the materials which can be used the cover element 2 in accordance with all the above-described embodiments and possible modifications can comprise an elastic material like for example a foam, wherein the edge regions (external skin) can form a closed surface. In connection with air inclusions due to the cellular structure of the foam, this affords a high degree of elasticity over a long service life, the air inclusions promoting uniform elastic properties in broad regions. The cover element 2 can also be formed from a two-component foam or a multi-component foam. After determining the individual contour of the lower portion and the printed circuit board 5 fitted therein including the components 6 and 7 arranged thereon the cover element can be produced for example by means of injection molding, in which case the two or more components of the foam are introduced into a predetermined mold. In comparison, metal spring elements which are inserted into a plastic part in known devices can become loosened and lose a part of their spring force.

To provide the above-described cover element 2 it is also possible to use silicone-based elastic materials which are introduced into a mold of suitable configuration by means of a nozzle. It is also possible to use plastic materials comprising two or more components, which elastic components can comprise for example silicone or TPE (thermoplastic elastomers). With the rubber-elastic properties inherent in those materials, the above-mentioned advantages like for example sealing integrity, vibration damping and an elastic holding and contact pressure function can be achieved at the same time and over a long service life. By means of the above-specified elastic materials it is possible to ensure the advantages of the present invention even in relation to uses involving large temperature fluctuations. Effective electrical insulation is also ensured.

While generally multi-part arrangements are known from the state of the art, in which there are provided a plurality of parts consisting of different materials for forming a cover member or a cover element or similar element and require a not inconsiderable manufacturing and assembly expense and complication, the solution according to the invention affords a marked simplification in the overall arrangement both in terms of manufacture of the cover element 2 and also assembly thereof. Further additional elements like for example spring elements of plastic or metal are not required.

The housing device 1 can serve to receive a circuit arrangement which is used for example for the actuation of electric motors in machines and in motor vehicles. The housing device 1 with the cover element 2 according to the invention can be arranged at any desired locations in an industrial machine or a motor vehicle and also in any desired position. The sealing action and mechanical stability in the sense of supporting the components 6 and 7 disposed on the printed circuit board 5 ensures a long service life, even in relation to severe mechanical loadings, without sealing integrity in relation to the ingress of dirt and moisture being worsened.

The present invention has been described in greater detail by means of embodiments by way of example with reference to the Figures. It is however self-evident to the man skilled in the art that the configuration of the present invention in accordance with the described Figures and the specified components and constituent parts in the Figures and the description and the further details by way of example are not to be interpreted restrictively. The invention is not limited to the specified views in the Figures, in particular dimensions and arrangements. All embodiments and variants which fall within the accompanying claims are deemed to belong to the invention.

What is claimed is:

1. A cover element connectable to a housing lower portion for covering same, wherein
the cover element is formed in one piece as a shaped portion,
the lower surface of the cover element, that faces in the direction of the lower portion, is so designed that it follows the contour of the inside surface of the lower portion, and
projections and recesses in the lower surface of the cover element are of such a configuration that recesses in the inside surface of the lower portion are at least partially filled and projections on the inside surface of the lower portion are at least partially surrounded in positively locking relationship.

2. The cover element as set forth in claim 1, wherein the inside surface of the lower portion is formed by a printed circuit board on which electric and electronic components are arranged and the cover element is adapted to follow the individual contour of the printed circuit board including the components.

3. The cover element as set forth in claim 2, wherein predetermined components arranged on the printed circuit board are at least partially surrounded by the cover element in positively locking relationship.

4. The cover element as set forth in claim 3, wherein at its lower surface the cover element has a contact surface which after connection of the cover element to the lower portion rests on an oppositely disposed contact surface of the lower portion in areal and sealing relationship.

5. The cover element as set forth in claim 4, wherein the first contact surface of the cover element projects into the lower portion when the cover element is fitted on to the lower portion.

6. The cover element as set forth in claim 5, wherein the first contact surface of the cover element partially rests on the printed circuit board and fixes the printed circuit board in the lower portion.

7. The cover element as set forth in claim 3, wherein provided at the lower surface of the cover element in the region of components arranged on the printed circuit board are projecting contact pressure regions which rest elastically on the respective components at predetermined locations thereon.

8. The cover element as set forth in claim 3, wherein the cover element has an annular contact surface at its lower surface and provided in the region of said contact surface is a contact pressure region which rests sealingly on the second contact surface of the lower portion and extends over the entire configuration of the annular contact surface of the cover element.

9. The cover element as set forth in claim 8, wherein the cover element is formed from a foam material with a component or with a plurality of components or from an elastic multi-component material on a silicone base or TPE.

10. A housing device comprising:
a housing lower portion into which a printed circuit board fitted with electric and electronic components can be fitted, and
a cover element as set forth in claim 1 for covering the lower portion.

11. The cover element as set forth in claim 1 wherein at its lower surface the cover element has a contact surface which after connection of the cover element to the lower portion rests on an oppositely disposed contact surface of the lower portion in areal and sealing relationship.

12. The cover element as set forth in claim 11, wherein the first contact surface of the cover element projects into the lower portion when the cover element is fitted on to the lower portion.

13. The cover element as set forth in claim 4, wherein the first contact surface of the cover element partially rests on the printed circuit board and fixes the printed circuit board in the lower portion.

14. The cover element as set forth in claim 2, wherein provided at the lower surface of the cover element in the region of components arranged on the printed circuit board are projecting contact pressure regions which rest elastically on the respective components at predetermined locations thereon.

15. The cover element as set forth in claim 1, wherein the cover element has an annular contact surface at its lower surface and provided in the region of said contact surface is a contact pressure region which rests sealingly on the second contact surface of the lower portion and extends over the entire configuration of the annular contact surface of the cover element.

16. The cover element as set forth in claim 1, wherein the cover element is formed from a foam material with a component or with a plurality of components or from an elastic multi-component material on a silicone base or TPE.
